(19) United States
(12) Patent Application Publication
(10) Pub. No.: US 2020/0304089 A1
(43) Pub. Date: Sep. 24, 2020

(54) WIDEBAND IMPEDANCE MATCHING NETWORK

(71) Applicant: WIN Semiconductors Corp., Tao Yuan City (TW)

(72) Inventors: Rachit Joshi, Tao Yuan City (TW); Shuo-Hung HSU, Tao Yuan City (TW); Yi-Wei LIEN, Tao Yuan City (TW); Wei-Chou WANG, Tao Yuan City (TW); Walter Tony WOHLMUTH, Tao Yuan City (TW)

(21) Appl. No.: 16/360,702

(22) Filed: Mar. 21, 2019

(51) Int. Cl. H03H 7/38; H01L 49/02; H01L 23/66; H03H 1/00

(52) U.S. Cl. CPC H03H 7/383; H01L 28/10; H01L 23/66; H01L 28/40; H01L 2223/6672; H03H 2001/0064; H01L 2223/6616; H01L 2223/6627; H03H 1/00

(57) ABSTRACT

A wideband impedance matching network comprises a fundamental output MN including a first portion and a second portion and a harmonic compensation MN including a harmonic MN portion and a harmonic MN backside-via inductor formed on an outer surface of a harmonic MN backside via hole penetrating through a semiconductor substrate. The first portion, the second portion and the harmonic MN portion are formed on the semiconductor substrate. A second terminal of the first portion and a first terminal of the second portion are connected to an RF output terminal. A first terminal of the harmonic MN portion and a first terminal of the first portion are connected to an RF input terminal. A second terminal of the harmonic MN portion is connected to a first terminal of the harmonic MN backside-via inductor. A second terminal of the harmonic MN backside-via inductor is grounded.

### FIELD OF THE INVENTION

The present invention is related to a wideband impedance matching network, especially a wideband impedance matching network having a backside via inductor.

### BACKGROUND OF THE INVENTION

Please refer to FIG. 4A, which illustrates a schematic diagram of an embodiment of a wideband impedance matching network of the conventional technology. Please also refer to FIG. 4B, which illustrates a top schematic view of an inductor of an embodiment of a wideband impedance matching network of the conventional technology. The wideband impedance matching network 9 of the conventional technology comprises three parts: a fundamental output matching network 991, an output harmonic compensation matching network 992, and an intermediate matching network 993. The fundamental output matching network 991 is a large 7C type matching network. The fundamental output matching network 991 comprises a first fundamental MN transmission line inductor 92, a second fundamental MN transmission line inductor 93, and a third fundamental MN transmission line inductor 94. The first fundamental MN transmission line inductor 92 has a first terminal 921 and a second terminal 922. The second fundamental MN transmission line inductor 93 has a first terminal 931 and a second terminal 932. The third fundamental MN transmission line inductor 94 has a first terminal 941 and a second terminal 942. The second terminal 922 of the first fundamental MN transmission line inductor 92 and the first terminal 941 of the third fundamental MN transmission line inductor 94 are connected to an RF output terminal 91. The second terminal 942 of the third fundamental MN transmission line inductor 94 is grounded. The intermediate matching network 993 comprises an intermediate MN inductor 96 and an intermediate MN capacitor 95. The intermediate MN capacitor 95 has a first terminal 951 and a second terminal 952. The intermediate MN inductor 96 has a first terminal 961 and a second terminal 962. The first terminal 921 of the first fundamental MN transmission line inductor 92 and the first terminal 931 of the second fundamental MN transmission line inductor 93 are connected to the second terminal 952 of the intermediate MN capacitor 95. The second terminal 932 of the second fundamental MN transmission line inductor 93 is grounded. The first terminal 951 of the intermediate MN capacitor 95 is connected to the second terminal 962 of the intermediate MN inductor 96. The output harmonic compensation matching network 992 comprises an output harmonic compensation MN inductor 97 and an output harmonic compensation MN capacitor 98. The output harmonic compensation MN inductor 97 has a first terminal 971 and a second terminal 972. The output harmonic compensation MN capacitor 98 has a first terminal 981 and a second terminal 982. The first terminal 961 of the intermediate MN inductor 96 and the first terminal 971 of the output harmonic compensation MN inductor 97 are connected to an RF input terminal. The second terminal 972 of the output harmonic compensation MN inductor 97 is connected to the first terminal 981 of the output harmonic compensation MN capacitor 98. The second terminal 982 is grounded. Conventional technology uses large inductors (including the intermediate MN inductor 96 and the output harmonic compensation MN inductor 97) and long transmission line inductors (including the first fundamental MN transmission line inductor 92, the second fundamental MN transmission line inductor 93, and the third fundamental MN transmission line inductor 94). The large inductors and the long transmission line inductors increase the chip size. Large chip size is mainly caused by the large inductors, especially the output harmonic compensation MN inductor 97. Furthermore, conventional class-F amplifier with conventional wideband impedance matching network 9 which has the large inductors and the long transmission line inductors can achieve about 1.2 GHz, 3 dB bandwidth, with 50% PAE (power-added efficiency). PAE of 50% is due to extra loss from the large inductors and the long transmission line inductors.

Accordingly, the present invention has developed a new design which may avoid the above mentioned drawbacks, may significantly enhance the performance of the devices and may take into account economic considerations. Therefore, the present invention then has been invented.

### SUMMARY OF THE INVENTION

The main technical problem that the present invention is seeking to solve is to find a new design of a wideband impedance matching network such that the chip size is significantly reduced, the PAE is significantly increased, and the bandwidth is significantly increased.

In order to solve the problems mentioned the above and to achieve the expected effect, the present invention provides a wideband impedance matching network comprising a fundamental output matching network and a harmonic compensation matching network. The fundamental output matching network is formed on a semiconductor substrate. The fundamental output matching network comprises a fundamental MN first portion and a fundamental MN second portion, wherein the fundamental MN first portion of the fundamental output matching network and the fundamental MN second portion of the fundamental output matching network are formed on a semiconductor substrate. The fundamental MN first portion has a first terminal and a second terminal. The fundamental MN second portion has a first terminal. The second terminal of the fundamental MN first portion and the first terminal of the fundamental MN second portion are connected to an RF output terminal. The harmonic compensation matching network comprises a harmonic MN portion and a harmonic MN backside via inductor. The harmonic MN portion is formed on the semiconductor substrate. The harmonic MN portion has a first terminal and a second terminal. The first terminal of the fundamental MN first portion and the first terminal of the harmonic MN portion are connected to an RF input terminal. The harmonic MN backside via inductor is formed on an outer surface of a harmonic MN backside via hole. The harmonic MN backside via hole penetrating through the semiconductor substrate. The harmonic MN backside via inductor has a first terminal and a second terminal. The second terminal of the harmonic MN portion is connected to the first terminal of the harmonic MN backside via inductor. The second terminal of the harmonic MN backside via inductor is grounded.

In an embodiment, the harmonic MN portion comprises a harmonic MN transmission line inductor.

In an embodiment, the harmonic MN portion further comprises a harmonic MN capacitor.

In an embodiment, the fundamental MN first portion comprises a first fundamental MN transmission line inductor.

In an embodiment, the fundamental MN first portion further comprises a first fundamental MN capacitor.

In an embodiment, the fundamental MN second portion comprises a second fundamental MN transmission line inductor.

In an embodiment, the harmonic MN portion further comprises a harmonic MN capacitor and the fundamental MN first portion further comprises a first fundamental MN capacitor.

In an embodiment, the semiconductor substrate further comprises a fundamental MN backside via hole and the fundamental output matching network further comprises a fundamental MN backside via inductor, wherein the fundamental MN backside via inductor is formed on an outer surface of the fundamental MN backside via hole, wherein the fundamental MN backside via hole penetrates through the semiconductor substrate, wherein the fundamental MN backside via inductor has a first terminal and a second terminal, wherein the fundamental MN second portion has a second terminal, wherein the second terminal of the fundamental MN second portion is connected to the first terminal of the fundamental MN backside via inductor, wherein the second terminal of the fundamental MN backside via inductor is grounded.

In an embodiment, the semiconductor substrate is selected from the group consisting of: GaAs, InP, GaN, SiC, Si, sapphire, and SiGe.

The present invention further provides a wideband impedance matching network comprising a harmonic compensation matching network and a fundamental output matching network. The harmonic compensation matching network is formed on a semiconductor substrate. The harmonic compensation matching network has a first terminal. The fundamental output matching network comprises a fundamental MN first portion, a fundamental MN second portion and a fundamental MN backside via inductor. The fundamental MN first portion is formed on the semiconductor substrate. The fundamental MN first portion has a first terminal and a second terminal. The first terminal of the fundamental MN first portion and the first terminal of the harmonic compensation matching network are connected to an RF input terminal. The fundamental MN second portion is formed on the semiconductor substrate. The fundamental MN second portion has a first terminal and a second terminal. The second terminal of the fundamental MN first portion and the first terminal of the fundamental MN second portion are connected to an RF output terminal. The fundamental MN backside via inductor is formed on an outer surface of a fundamental MN backside via hole. The fundamental MN backside via hole penetrating through the semiconductor substrate. The fundamental MN backside via inductor has a first terminal and a second terminal. The second terminal of the fundamental MN second portion is connected to the first terminal of the fundamental MN backside via inductor. The second terminal of the fundamental MN backside via inductor is grounded.

In an embodiment, the harmonic compensation matching network comprises a harmonic MN transmission line inductor.

In an embodiment, the harmonic compensation matching network further comprises a harmonic MN capacitor.

In an embodiment, the fundamental MN first portion comprises a first fundamental MN transmission line inductor.

In an embodiment, the fundamental MN first portion further comprises a first fundamental MN capacitor.

In an embodiment, the fundamental MN second portion comprises a second fundamental MN transmission line inductor.

In an embodiment, the harmonic compensation matching network further comprises a harmonic MN capacitor and the fundamental MN first portion further comprises a first fundamental MN capacitor.

In an embodiment, the semiconductor substrate is selected from the group consisting of: GaAs, InP, GaN, SiC, Si, sapphire, and SiGe.

For further understanding the characteristics and effects of the present invention, some preferred embodiments referred to drawings are in detail described as follows.

### BRIEF DESCRIPTION OF DRAWINGS

FIG. 1A illustrates a schematic diagram of an embodiment of a wideband impedance matching network of the present invention.

FIG. 1B illustrates a cross-sectional schematic view of a harmonic MN backside via inductor of FIG. 1A.

FIG. 1C˜FIG. 1M illustrate the schematic diagrams of the embodiments of a wideband impedance matching network of the present invention.

FIG. 2A illustrates a schematic diagram of an embodiment of a wideband impedance matching network of the present invention.

FIG. 2B illustrates a cross-sectional schematic view of a harmonic MN backside via inductor and a fundamental MN backside via inductor of FIG. 2A.

FIG. 2C˜FIG. 2M illustrate the schematic diagrams of the embodiments of a wideband impedance matching network of the present invention.

FIG. 3A illustrates a schematic diagram of an embodiment of a wideband impedance matching network of the present invention.

FIG. 3B illustrates a cross-sectional schematic view of a fundamental MN backside via inductor of FIG. 3A.

FIG. 3C˜FIG. 3M illustrate the schematic diagrams of the embodiments of a wideband impedance matching network of the present invention.

FIG. 4A illustrates a schematic diagram of an embodiment of a wideband impedance matching network of the conventional technology.

FIG. 4B illustrates a top schematic view of an inductor of an embodiment of a wideband impedance matching network of the conventional technology.

### DETAILED DESCRIPTIONS OF PREFERRED EMBODIMENTS

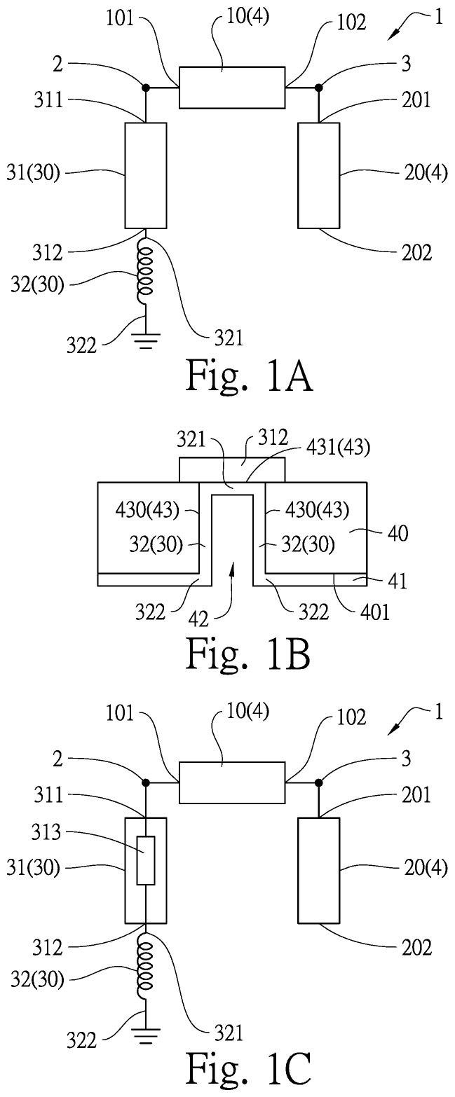

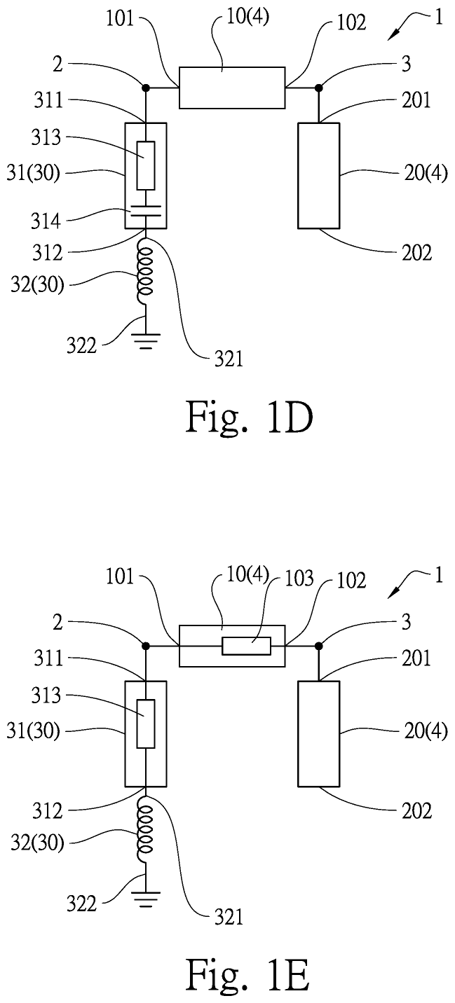

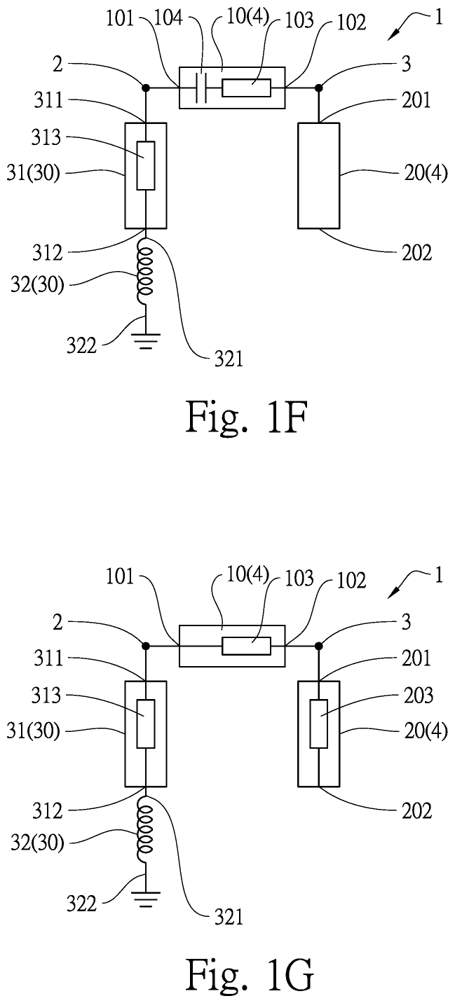

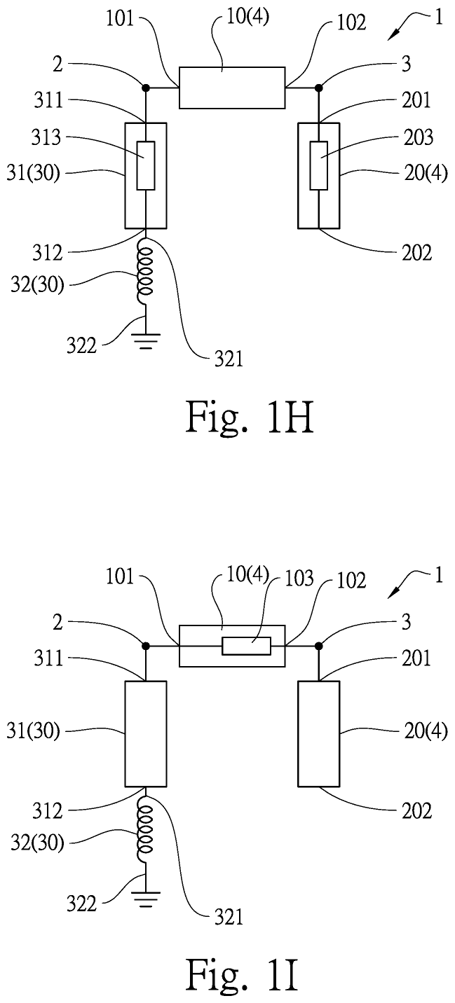

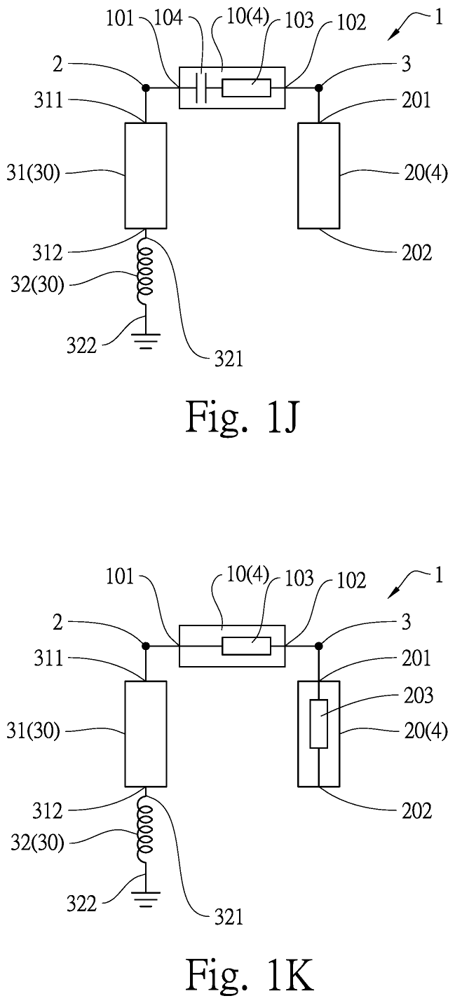

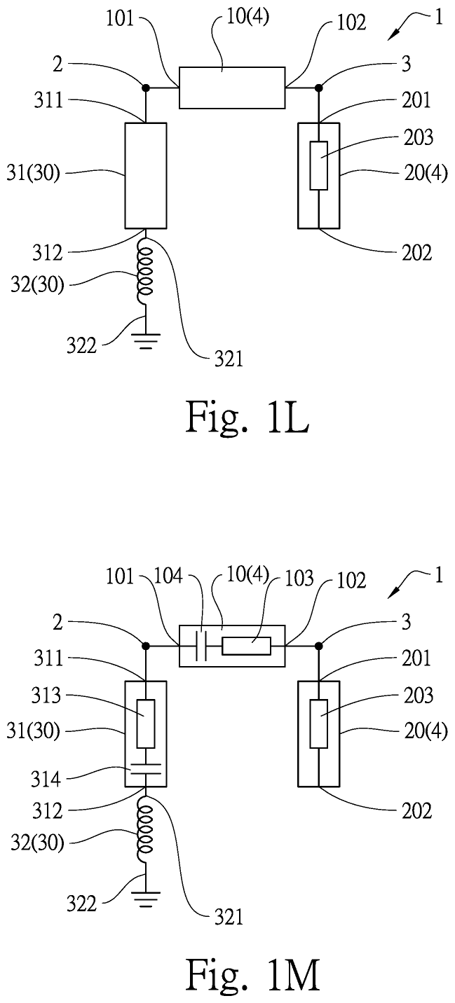

Please refer to FIG. 1A, which illustrates a schematic diagram of an embodiment of a wideband impedance matching network of the present invention. A wideband impedance matching network 1 of the present invention comprises a fundamental output matching network 4 and a harmonic compensation matching network 30. The fundamental output matching network 4 comprises a fundamental MN first portion 10 and a fundamental MN second portion 20. The fundamental MN first portion 10 has a first terminal 101 and a second terminal 102. The fundamental MN second portion 20 has a first terminal 201 and a second terminal 202. The second terminal 102 of the fundamental MN first portion 10 and the first terminal 201 of the fundamental MN second portion 20 are connected to an RF output terminal 3. The harmonic compensation matching network 30 comprises a harmonic MN portion 31 and a harmonic MN backside via inductor 32. Please also refer to FIG. 1B, which illustrates a cross-sectional schematic view of a harmonic MN backside via inductor of FIG. 1A. A semiconductor substrate 40 comprises a harmonic MN backside via hole 42. The harmonic MN backside via hole 42 penetrates through the semiconductor substrate 40. The fundamental MN first portion 10 of the fundamental output matching network 4, the fundamental MN second portion 20 of the fundamental output matching network 4, and the harmonic MN portion 31 of the harmonic compensation matching network 30 are formed on the semiconductor substrate 40. The harmonic MN portion 31 has a first terminal 311 and a second terminal 312. The first terminal 101 of the fundamental MN first portion 10 and the first terminal 311 of the harmonic MN portion 31 are connected to an RF input terminal 2. The harmonic MN backside via hole 42 has an outer surface 43. The outer surface 43 of the harmonic MN backside via hole 42 includes a surrounding surface 430 of the harmonic MN backside via hole 42 and a bottom surface 431 of the harmonic MN backside via hole 42. In current embodiment, the surrounding surface 430 of the harmonic MN backside via hole 42 is defined by the semiconductor substrate 40, while the bottom surface 431 of the harmonic MN backside via hole 42 is defined by the second terminal 312 of the harmonic MN portion 31. A backside metal layer 41 is formed a bottom surface 401 of the semiconductor substrate 40 and the outer surface 43 of the harmonic MN backside via hole 42 (including the surrounding surface 430 of the harmonic MN backside via hole 42 and the bottom surface 431 of the harmonic MN backside via hole 42). The backside metal layer 41 includes two parts: (1) the first part: the backside metal layer 41 formed on the bottom surface 401 of the semiconductor substrate 40, and (2) the second part: the backside metal layer 41 formed on outer surface 43 of the harmonic MN backside via hole 42 (including the surrounding surface 430 of the harmonic MN backside via hole 42 and the bottom surface 431 of the harmonic MN backside via hole 42). The first part of the backside metal layer 41 (the backside metal layer 41 formed on the bottom surface 401 of the semiconductor substrate 40) is grounded. The second part of the backside metal layer 41 forms the harmonic MN backside via inductor 32 that is that the backside metal layer 41 formed on outer surface 43 of the harmonic MN backside via hole 42 (including the surrounding surface 430 of the harmonic MN backside via hole 42 and the bottom surface 431 of the harmonic MN backside via hole 42) forms the harmonic MN backside via inductor 32. The harmonic MN backside via inductor 32 has a first terminal 321 and a second terminal 322. The first terminal 321 of the harmonic MN backside via inductor 32 is the backside metal layer 41 formed on the bottom surface 431 of the harmonic MN backside via hole 42. The first terminal 321 of the harmonic MN backside via inductor 32 is electrically connected to the second terminal 312 of the harmonic MN portion 31. The second terminal 322 of the harmonic MN backside via inductor 32 is connected to the first part of the backside metal layer 41 (the backside metal layer 41 formed on the bottom surface 401 of the semiconductor substrate 40). Hence, the second terminal 322 of the harmonic MN backside via inductor 32 is grounded through the first part of the backside metal layer 41 (the backside metal layer 41 formed on the bottom surface 401 of the semiconductor substrate 40). In some embodiments, the second terminal 202 of the fundamental MN second portion 20 is open. In some preferable embodiments, the second terminal 202 of the fundamental MN second portion 20 is grounded. In some embodiments, the semiconductor substrate 40 is selected from the group consisting of: GaAs, InP, GaN, SiC, Si, sapphire, and SiGe. The present invention uses the harmonic MN backside via inductor 32 to replace the conventional large inductor. Obviously, the chip size can be significantly reduced. Furthermore, the extra loss from the harmonic MN backside via inductor 32 can be reduced such that the PAE can be significantly increased. Using the design of the wideband impedance matching network 1 of the present invention, the PAE may be increased to 66%. Moreover, since the bandwidth of the harmonic MN backside via inductor 32 is very wide (from DC up to 90.2 GHz) and with relatively small inductance, the bandwidth of the harmonic MN backside via inductor 32 becomes very useful in practical design for the wideband impedance matching network 1 of the present invention. The bandwidth of the wideband impedance matching network 1 of the present invention may be increased to 2.1 GHz. The design concept is simple to implement and easy to design for 2^{nd} and 3^{rd} harmonic. Without using the conventional large inductor, the chip size may be reduced to 2.4 times smaller than the conventional chip size. The harmonic MN backside via inductor 32 as part of the wideband impedance matching network 1 of the present invention in high order harmonic termination can be used on III-V(GaAs or InP or GaN), or Si, or SiGe semiconductor technology platform for MIMIC applications. The feature of small inductance value of the harmonic MN backside via inductor 32 as part of the wideband impedance matching network 1 of the present invention is practically useful as high order harmonic terminations. Moreover, not only the chip size is shrinking, the bandwidth is increase, but the Pout (output power) is also increased. The inductance value of the harmonic MN backside via inductor 32 of the present invention can be designed by the shape of the harmonic MN backside via inductor 32, the size of the harmonic MN backside via inductor 32, the depth of the harmonic MN backside via hole 42, the thickness of the backside metal layer 41, and the material of the backside metal layer 41. Further tuning of third harmonic impedance is expected to improve PAE further to reach 70%. The harmonic compensation matching network 30 and the fundamental output matching network 4 form a pi-type wideband impedance matching network 1 of the present invention to achieve a wide bandwidth. The harmonic MN backside via inductor 32 combines with the pi-type wideband impedance matching network 1 of the present invention can achieve a low loss and wideband matching network for harmonic termination.

Please refer to FIG. 1C, which illustrates a schematic diagram of an embodiment of a wideband impedance matching network of the present invention. The main structure of the embodiment of FIG. 1C is basically the same as the structure of the embodiment of FIG. 1A, except that the harmonic MN portion 31 comprises a harmonic MN transmission line inductor 313. Please refer to FIG. 1D, which illustrates a schematic diagram of an embodiment of a wideband impedance matching network of the present invention. The main structure of the embodiment of FIG. 1D is basically the same as the structure of the embodiment of FIG. 1C, except that the harmonic MN portion 31 further comprises a harmonic MN capacitor 314. The harmonic MN transmission line inductor 313 is connected to the harmonic MN capacitor 314.

Please refer to FIG. 1E, which illustrates a schematic diagram of an embodiment of a wideband impedance matching network of the present invention. The main structure of the embodiment of FIG. 1E is basically the same as the structure of the embodiment of FIG. 1C, except that the fundamental MN first portion 10 comprises a first fundamental MN transmission line inductor 103. Please refer to FIG. 1F, which illustrates a schematic diagram of an embodiment of a wideband impedance matching network of the present invention. The main structure of the embodiment of FIG. 1F is basically the same as the structure of the embodiment of FIG. 1E, except that the fundamental MN first portion 10 further comprises a first fundamental MN capacitor 104.

Please refer to FIG. 1G, which illustrates a schematic diagram of an embodiment of a wideband impedance matching network of the present invention. The main structure of the embodiment of FIG. 1G is basically the same as the structure of the embodiment of FIG. 1E, except that the fundamental MN second portion 20 comprises a second fundamental MN transmission line inductor 203.

Please refer to FIG. 1H, which illustrates a schematic diagram of an embodiment of a wideband impedance matching network of the present invention. The main structure of the embodiment of FIG. 1H is basically the same as the structure of the embodiment of FIG. 1C, except that the fundamental MN second portion 20 comprises a second fundamental MN transmission line inductor 203.

Please refer to FIG. 1I, which illustrates a schematic diagram of an embodiment of a wideband impedance matching network of the present invention. The main structure of the embodiment of FIG. 1I is basically the same as the structure of the embodiment of FIG. 1A, except that the fundamental MN first portion 10 comprises a first fundamental MN transmission line inductor 103. Please refer to FIG. 1J, which illustrates a schematic diagram of an embodiment of a wideband impedance matching network of the present invention. The main structure of the embodiment of FIG. 1J is basically the same as the structure of the embodiment of FIG. 1I, except that the fundamental MN first portion 10 further comprises a first fundamental MN capacitor 104.

Please refer to FIG. 1K, which illustrates a schematic diagram of an embodiment of a wideband impedance matching network of the present invention. The main structure of the embodiment of FIG. 1K is basically the same as the structure of the embodiment of FIG. 1I, except that the fundamental MN second portion 20 comprises a second fundamental MN transmission line inductor 203.

Please refer to FIG. 1L, which illustrates a schematic diagram of an embodiment of a wideband impedance matching network of the present invention. The main structure of the embodiment of FIG. 1L is basically the same as the structure of the embodiment of FIG. 1A, except that the fundamental MN second portion 20 comprises a second fundamental MN transmission line inductor 203.

Please refer to FIG. 1M, which illustrates a schematic diagram of an embodiment of a wideband impedance matching network of the present invention. The main structure of the embodiment of FIG. 1M is basically the same as the structure of the embodiment of FIG. 1G, except that the harmonic MN portion 31 further comprises a harmonic MN capacitor 314 and the fundamental MN first portion 10 further comprises a first fundamental MN capacitor 104.

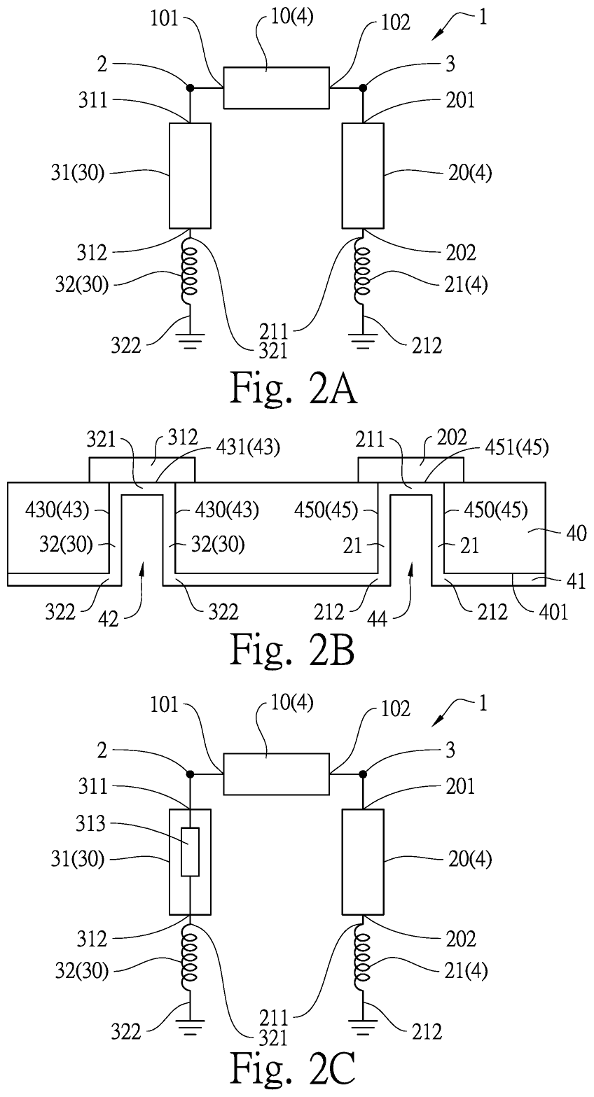

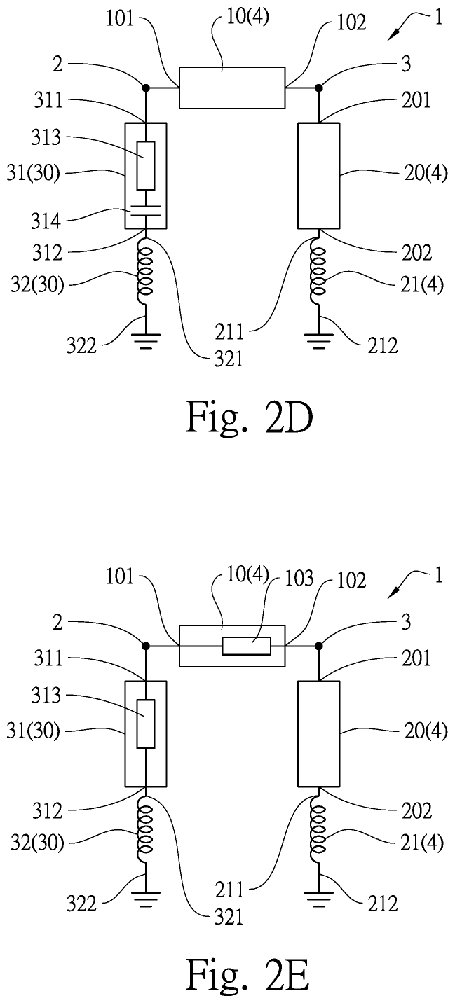

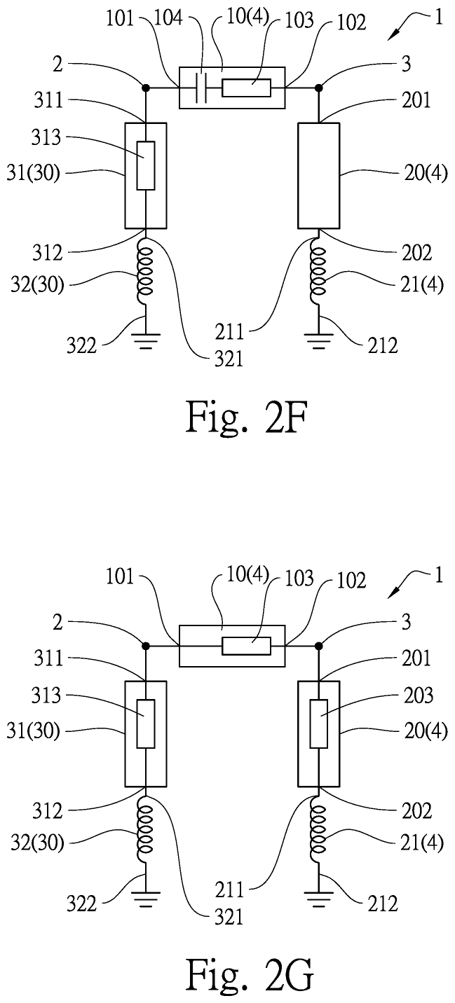

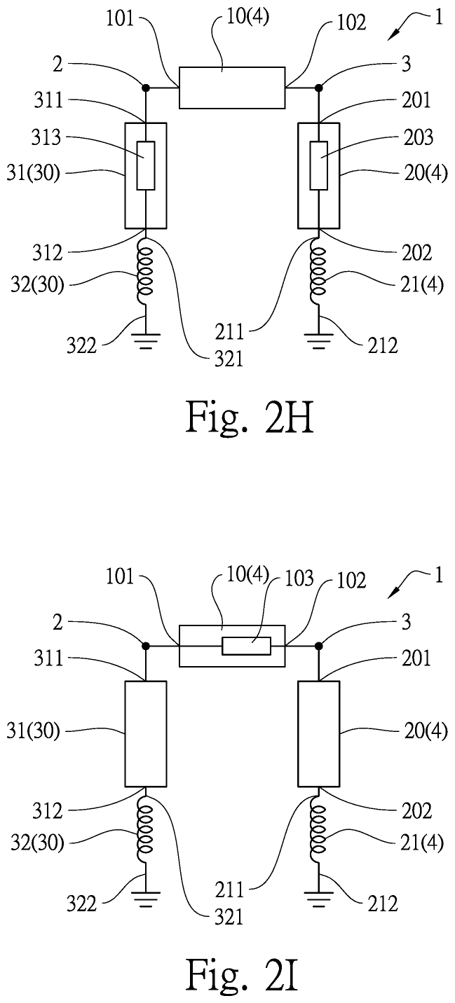

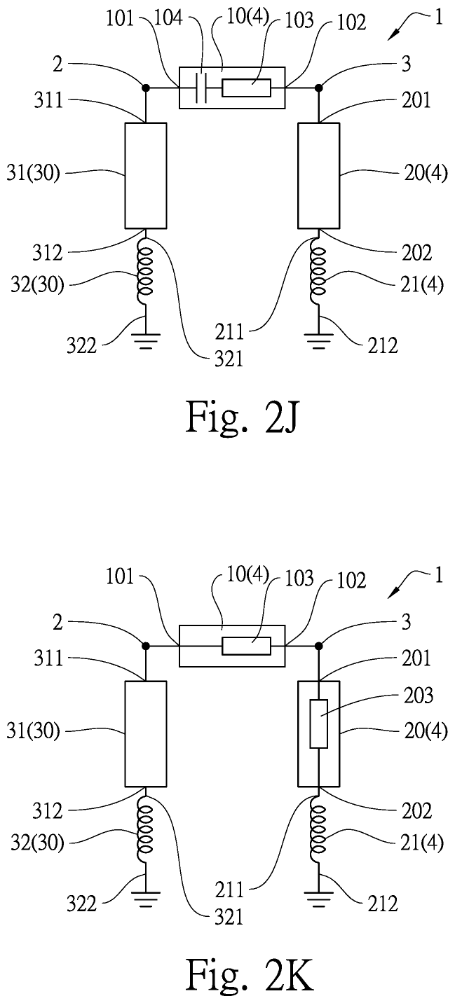

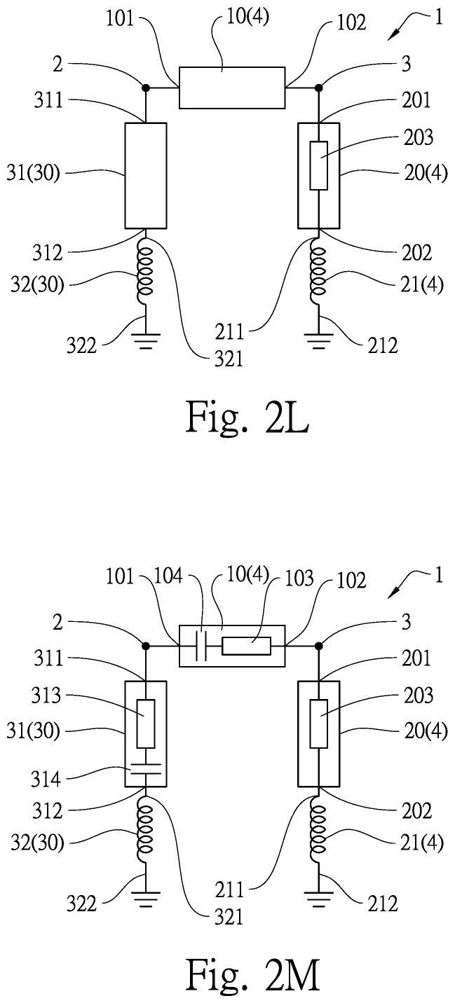

Please refer to FIG. 2A, which illustrates a schematic diagram of an embodiment of a wideband impedance matching network of the present invention. Please also refer to FIG. 2B, which illustrates a cross-sectional schematic view of a harmonic MN backside via inductor of FIG. 2A. The main structure of the embodiment of FIGS. 2A and 2B is basically the same as the structure of the embodiment of FIGS. 1A and 1B, except that the semiconductor substrate 40 further comprises a fundamental MN backside via hole 44 and the fundamental output matching network 4 further comprises a fundamental MN backside via inductor 21. The fundamental MN backside via hole 44 penetrates through the semiconductor substrate 40. The fundamental MN backside via hole 44 has an outer surface 45. The outer surface 45 of the fundamental MN backside via hole 44 includes a surrounding surface 450 of the fundamental MN backside via hole 44 and a bottom surface 451 of the fundamental MN backside via hole 44. In current embodiment, the surrounding surface 450 of the fundamental MN backside via hole 44 is defined by the semiconductor substrate 40, while the bottom surface 451 of the fundamental MN backside via hole 44 is defined by the second terminal 202 of the fundamental MN second portion 20. The backside metal layer 41 is formed the bottom surface 401 of the semiconductor substrate 40, the outer surface 43 of the harmonic MN backside via hole 42 (including the surrounding surface 430 of the harmonic MN backside via hole 42 and the bottom surface 431 of the harmonic MN backside via hole 42), and the outer surface 45 of the fundamental MN backside via hole 44 (including the surrounding surface 450 of the fundamental MN backside via hole 44 and the bottom surface 451 of the fundamental MN backside via hole 44). The backside metal layer 41 includes three parts: (1) the first part: the backside metal layer 41 formed on the bottom surface 401 of the semiconductor substrate 40, (2) the second part: the backside metal layer 41 formed on outer surface 43 of the harmonic MN backside via hole 42 (including the surrounding surface 430 of the harmonic MN backside via hole 42 and the bottom surface 431 of the harmonic MN backside via hole 42), and (3) the third part: the backside metal layer 41 formed on outer surface 45 of the fundamental MN backside via hole 44 (including the surrounding surface 450 of the fundamental MN backside via hole 44 and the bottom surface 451 of the fundamental MN backside via hole 44). The third part of the backside metal layer 41 forms the fundamental MN backside via inductor 21 that is that the backside metal layer 41 formed on outer surface 45 of the fundamental MN backside via hole 44 (including the surrounding surface 450 of the fundamental MN backside via hole 44 and the bottom surface 451 of the fundamental MN backside via hole 44) forms the fundamental MN backside via inductor 21. The fundamental MN backside via inductor 21 has a first terminal 211 and a second terminal 212. The first terminal 211 of the fundamental MN backside via inductor 21 is the backside metal layer 41 formed on the bottom surface 451 of the fundamental MN backside via hole 44. The first terminal 211 of the fundamental MN backside via inductor 21 is electrically connected to the second terminal 202 of the fundamental MN second portion 20. The second terminal 212 of the fundamental MN backside via inductor 21 is connected to the first part of the backside metal layer 41 (the backside metal layer 41 formed on the bottom surface 401 of the semiconductor substrate 40). Hence, the second terminal 212 of the fundamental MN backside via inductor 21 is grounded through the first part of the backside metal layer 41 (the backside metal layer 41 formed on the bottom surface 401 of the semiconductor substrate 40). In some embodiments, the semiconductor substrate 40 is selected from the group consisting of: GaAs, InP, GaN, SiC, Si, sapphire, and SiGe. The present invention uses the harmonic MN backside via inductor 32 and the fundamental MN backside via inductor 21 to replace the conventional large inductor. Obviously, the chip size can be significantly reduced. Furthermore, the extra loss from the harmonic MN backside via inductor 32 and the fundamental MN backside via inductor 21 can be reduced such that the PAE can be significantly increased. Using the design of the wideband impedance matching network 1 of the present invention, the PAE may be increased to 66%. Moreover, since the band width of the harmonic MN backside via inductor 32 and the bandwidth of the fundamental MN backside via inductor 21 are very wide (from DC up to 90.2 GHz) and with relatively small inductance, the band width of the harmonic MN backside via inductor 32 and the bandwidth of the fundamental MN backside via inductor 21 become very useful in practical design for the wideband impedance matching network 1 of the present invention. The bandwidth of the wideband impedance matching network 1 of the present invention may be increased to 2.1 GHz. The design concept is simple to implement and easy to design for 2^{nd} and 3^{rd} harmonic. Without using the conventional large inductor, the chip size may be reduced to 2.4 times smaller than the conventional chip size. The harmonic MN backside via inductor 32 and the fundamental MN backside via inductor 21 as parts of the wideband impedance matching network 1 of the present invention in high order harmonic termination can be used on III-V(GaAs or InP or GaN), or Si, or SiGe semiconductor technology platform for MMIC applications. The feature of small inductance values of the harmonic MN backside via inductor 32 and the fundamental MN backside via inductor 21 as parts of the wideband impedance matching network 1 of the present invention is practically useful as high order harmonic terminations. Moreover, not only the chip size is shrinking, the bandwidth is increase, but the Pout (output power) is also increased. The inductance values of the harmonic MN backside via inductor 32 and the fundamental MN backside via inductor 21 of the present invention can be designed by the shapes of the harmonic MN backside via inductor 32 and the fundamental MN backside via inductor 21, the sizes of the harmonic MN backside via inductor 32 and the fundamental MN backside via inductor 21, the depths of the harmonic MN backside via hole 42 and the fundamental MN backside via hole 44, the thickness of the backside metal layer 41, and the material of the backside metal layer 41. Further tuning of third harmonic impedance is expected to improve PAE further to reach 70%. The harmonic compensation matching network 30 and the fundamental output matching network 4 form a pi-type wideband impedance matching network 1 of the present invention to achieve a wide bandwidth. The harmonic MN backside via inductor 32 and the fundamental MN backside via inductor 21 combine with the pi-type wideband impedance matching network 1 of the present invention can achieve a low loss and wideband matching network for harmonic termination.

Please refer to FIG. 2C, which illustrates a schematic diagram of an embodiment of a wideband impedance matching network of the present invention. The main structure of the embodiment of FIG. 2C is basically the same as the structure of the embodiment of FIG. 2A, except that the harmonic MN portion 31 comprises a harmonic MN transmission line inductor 313. Please refer to FIG. 2D, which illustrates a schematic diagram of an embodiment of a wideband impedance matching network of the present invention. The main structure of the embodiment of FIG. 2D is basically the same as the structure of the embodiment of FIG. 2C, except that the harmonic MN portion 31 further comprises a harmonic MN capacitor 314. The harmonic MN transmission line inductor 313 is connected to the harmonic MN capacitor 314.

Please refer to FIG. 2E, which illustrates a schematic diagram of an embodiment of a wideband impedance matching network of the present invention. The main structure of the embodiment of FIG. 2E is basically the same as the structure of the embodiment of FIG. 2C, except that the fundamental MN first portion 10 comprises a first fundamental MN transmission line inductor 103. Please refer to FIG. 2F, which illustrates a schematic diagram of an embodiment of a wideband impedance matching network of the present invention. The main structure of the embodiment of FIG. 2F is basically the same as the structure of the embodiment of FIG. 2E, except that the fundamental MN first portion 10 further comprises a first fundamental MN capacitor 104.

Please refer to FIG. 2G, which illustrates a schematic diagram of an embodiment of a wideband impedance matching network of the present invention. The main structure of the embodiment of FIG. 2G is basically the same as the structure of the embodiment of FIG. 2E, except that the fundamental MN second portion 20 comprises a second fundamental MN transmission line inductor 203.

Please refer to FIG. 2H, which illustrates a schematic diagram of an embodiment of a wideband impedance matching network of the present invention. The main structure of the embodiment of FIG. 2H is basically the same as the structure of the embodiment of FIG. 2C, except that the fundamental MN second portion 20 comprises a second fundamental MN transmission line inductor 203.

Please refer to FIG. 21, which illustrates a schematic diagram of an embodiment of a wideband impedance matching network of the present invention. The main structure of the embodiment of FIG. 21 is basically the same as the structure of the embodiment of FIG. 2A, except that the fundamental MN first portion 10 comprises a first fundamental MN transmission line inductor 103. Please refer to FIG. 2J, which illustrates a schematic diagram of an embodiment of a wideband impedance matching network of the present invention. The main structure of the embodiment of FIG. 2J is basically the same as the structure of the embodiment of FIG. 21, except that the fundamental MN first portion 10 further comprises a first fundamental MN capacitor 104.

Please refer to FIG. 2K, which illustrates a schematic diagram of an embodiment of a wideband impedance matching network of the present invention. The main structure of the embodiment of FIG. 2K is basically the same as the structure of the embodiment of FIG. 21, except that the fundamental MN second portion 20 comprises a second fundamental MN transmission line inductor 203.

Please refer to FIG. 2L, which illustrates a schematic diagram of an embodiment of a wideband impedance matching network of the present invention. The main structure of the embodiment of FIG. 2L is basically the same as the structure of the embodiment of FIG. 2A, except that the fundamental MN second portion 20 comprises a second fundamental MN transmission line inductor 203.

Please refer to FIG. 2M, which illustrates a schematic diagram of an embodiment of a wideband impedance matching network of the present invention. The main structure of the embodiment of FIG. 2M is basically the same as the structure of the embodiment of FIG. 2G, except that the harmonic MN portion 31 further comprises a harmonic MN capacitor 314 and the fundamental MN first portion 10 further comprises a first fundamental MN capacitor 104.

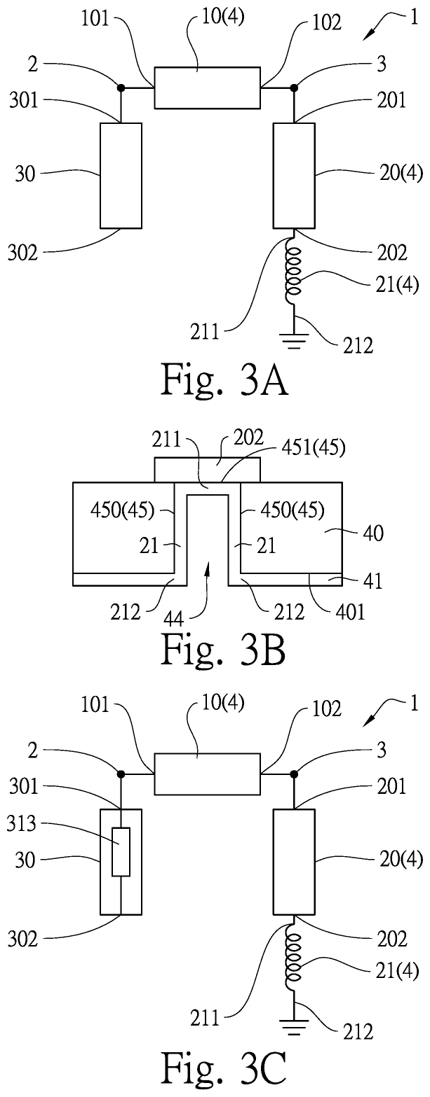

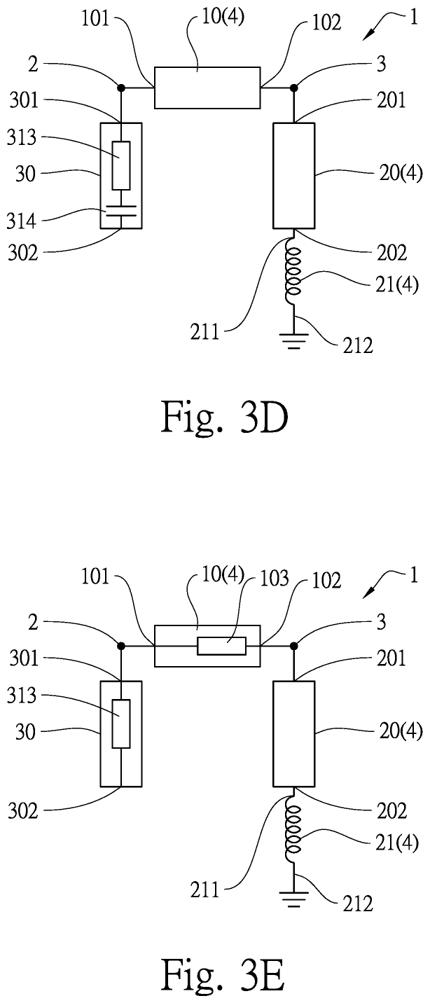

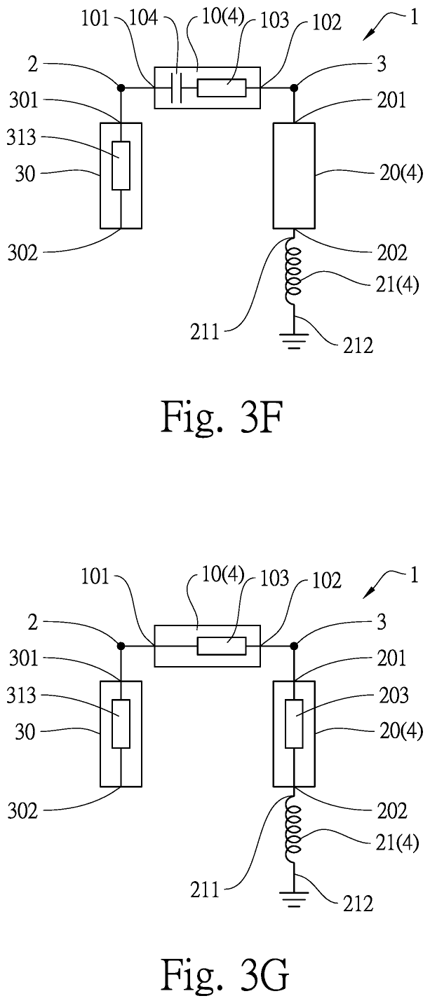

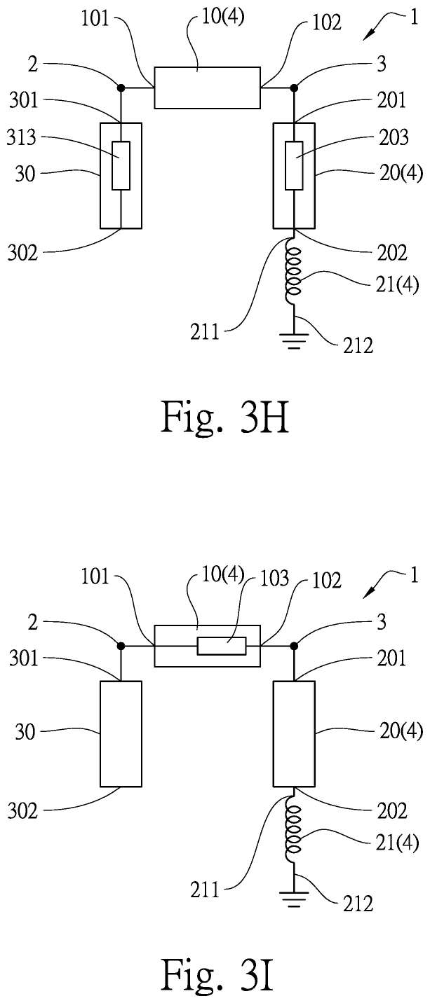

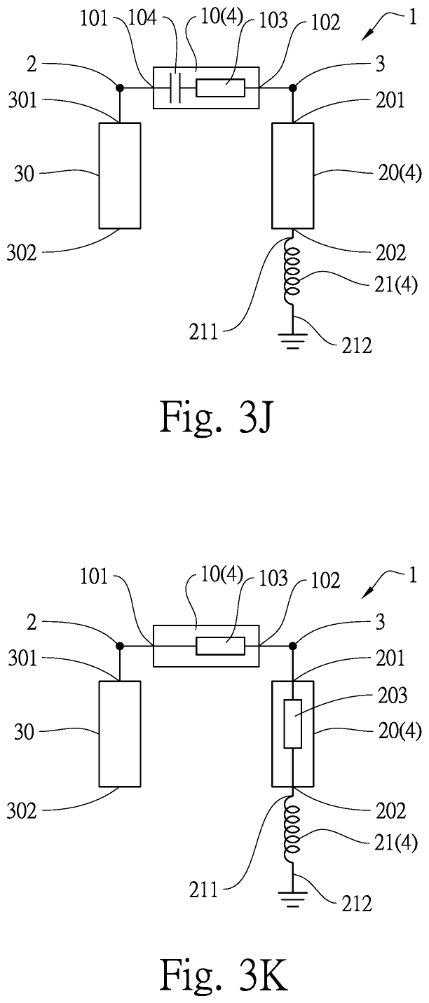

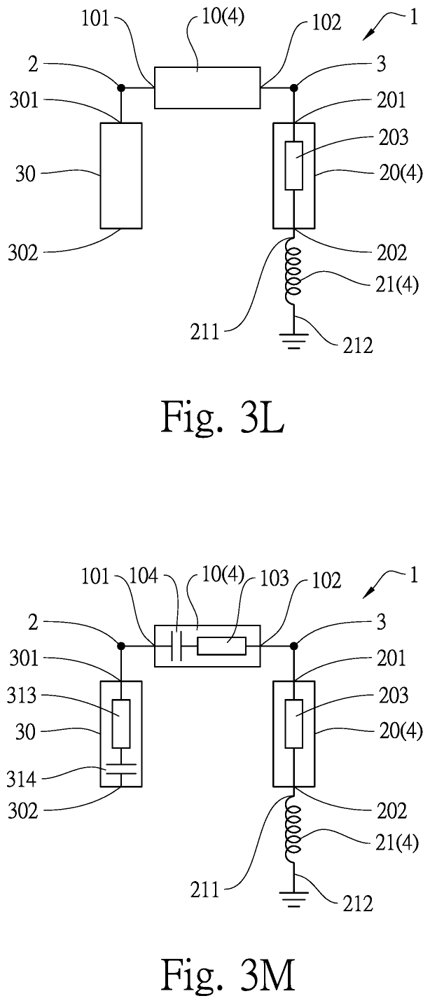

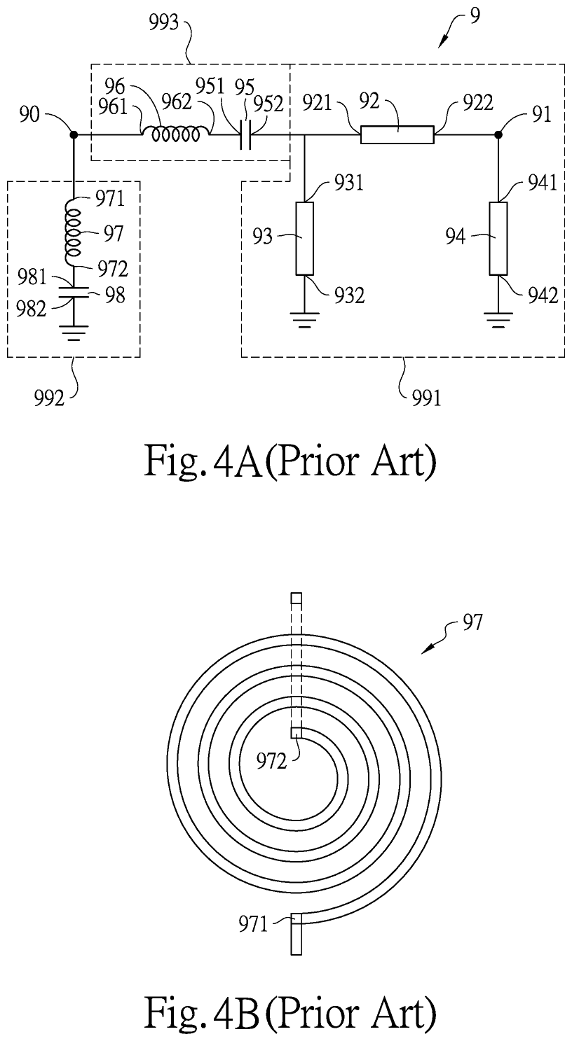

Please refer to FIG. 3A, which illustrates a schematic diagram of an embodiment of a wideband impedance matching network of the present invention. A wideband impedance matching network 1 of the present invention comprises a fundamental output matching network 4 and a harmonic compensation matching network 30. The fundamental output matching network 4 comprises a fundamental MN first portion 10, a fundamental MN second portion 20, and a fundamental MN backside via inductor 21. The harmonic compensation matching network 30 has a first terminal 301 and a second terminal 302. The fundamental MN first portion 10 has a first terminal 101 and a second terminal 102. The first terminal 101 of the fundamental MN first portion 10 and the first terminal 301 of the harmonic compensation matching network 30 are connected to an RF input terminal 2. The fundamental MN second portion 20 has a first terminal 201 and a second terminal 202. The second terminal 102 of the fundamental MN first portion 10 and the first terminal 201 of the fundamental MN second portion 20 are connected to an RF output terminal 3. Please also refer to FIG. 3B, which illustrates a cross-sectional schematic view of a harmonic MN backside via inductor of FIG. 3A. A semiconductor substrate 40 comprises a fundamental MN backside via hole 44. The fundamental MN backside via hole 44 penetrates through the semiconductor substrate 40. The harmonic compensation matching network 30, the fundamental MN first portion 10, and the fundamental MN second portion 20 are formed on a semiconductor substrate 40. The fundamental MN backside via hole 44 has an outer surface 45. The outer surface 45 of the fundamental MN backside via hole 44 includes a surrounding surface 450 of the fundamental MN backside via hole 44 and a bottom surface 451 of the fundamental MN backside via hole 44. In current embodiment, the surrounding surface 450 of the fundamental MN backside via hole 44 is defined by the semiconductor substrate 40, while the bottom surface 451 of the fundamental MN backside via hole 44 is defined by the second terminal 202 of the fundamental MN second portion 20. The backside metal layer 41 is formed the bottom surface 401 of the semiconductor substrate 40 and the outer surface 45 of the fundamental MN backside via hole 44 (including the surrounding surface 450 of the fundamental MN backside via hole 44 and the bottom surface 451 of the fundamental MN backside via hole 44). The backside metal layer 41 includes two parts: (1) the first part: the backside metal layer 41 formed on the bottom surface 401 of the semiconductor substrate 40, and (2) the second part: the backside metal layer 41 formed on outer surface 45 of the fundamental MN backside via hole 44 (including the surrounding surface 450 of the fundamental MN backside via hole 44 and the bottom surface 451 of the fundamental MN backside via hole 44). The third part of the backside metal layer 41 forms the fundamental MN backside via inductor 21 that is that the backside metal layer 41 formed on outer surface 45 of the fundamental MN backside via hole 44 (including the surrounding surface 450 of the fundamental MN backside via hole 44 and the bottom surface 451 of the fundamental MN backside via hole 44) forms the fundamental MN backside via inductor 21. The fundamental MN backside via inductor 21 has a first terminal 211 and a second terminal 212. The first terminal 211 of the fundamental MN backside via inductor 21 is the backside metal layer 41 formed on the bottom surface 451 of the fundamental MN backside via hole 44. The first terminal 211 of the fundamental MN backside via inductor 21 is electrically connected to the second terminal 202 of the fundamental MN second portion 20. The second terminal 212 of the fundamental MN backside via inductor 21 is connected to the first part of the backside metal layer 41 (the backside metal layer 41 formed on the bottom surface 401 of the semiconductor substrate 40). Hence, the second terminal 212 of the fundamental MN backside via inductor 21 is grounded through the first part of the backside metal layer 41 (the backside metal layer 41 formed on the bottom surface 401 of the semiconductor substrate 40). In some embodiments, the second terminal 302 of the harmonic compensation matching network 30 is open. In some preferable embodiments, the second terminal 302 of the harmonic compensation matching network 30 is grounded. In some embodiments, the semiconductor substrate 40 is selected from the group consisting of: GaAs, InP, GaN, SiC, Si, sapphire, and SiGe. The present invention uses the fundamental MN backside via inductor 21 to replace the conventional large inductor. Obviously, the chip size can be significantly reduced. Furthermore, the extra loss from the fundamental MN backside via inductor 21 can be reduced such that the PAE can be significantly increased. Using the design of the wideband impedance matching network 1 of the present invention, the PAE may be increased to 66%. Moreover, since the bandwidth of the fundamental MN backside via inductor 21 is very wide (from DC up to 90.2 GHz) and with relatively small inductance, the bandwidth of the fundamental MN backside via inductor 21 becomes very useful in practical design for the wideband impedance matching network 1 of the present invention. The bandwidth of the wideband impedance matching network 1 of the present invention may be increased to 2.1 GHz. The design concept is simple to implement and easy to design for 2^{nd} and 3^{rd} harmonic. Without using the conventional large inductor, the chip size may be reduced to 2.4 times smaller than the conventional chip size. The fundamental MN backside via inductor 21 as part of the wideband impedance matching network 1 of the present invention in high order harmonic termination can be used on III-V(GaAs or InP or GaN), or Si, or SiGe semiconductor technology platform for MMIC applications. The feature of small inductance value of the fundamental MN backside via inductor 21 as part of the wideband impedance matching network 1 of the present invention is practically useful as high order harmonic terminations. Moreover, not only the chip size is shrinking, the bandwidth is increase, but the Pout (output power) is also increased. The inductance value of the fundamental MN backside via inductor 21 of the present invention can be designed by the shape of the fundamental MN backside via inductor 21, the size of the fundamental MN backside via inductor 21, the depth of the fundamental MN backside via hole 44, the thickness of the backside metal layer 41, and the material of the backside metal layer 41. Further tuning of third harmonic impedance is expected to improve PAE further to reach 70%. The harmonic compensation matching network 30 and the fundamental output matching network 4 form a pi-type wideband impedance matching network 1 of the present invention to achieve a wide bandwidth. The fundamental MN backside via inductor 21 combines with the pi-type wideband impedance matching network 1 of the present invention can achieve a low loss and wideband matching network for harmonic termination.

Please refer to FIG. 3C, which illustrates a schematic diagram of an embodiment of a wideband impedance matching network of the present invention. The main structure of the embodiment of FIG. 3C is basically the same as the structure of the embodiment of FIG. 3A, except that the harmonic compensation matching network 30 comprises a harmonic MN transmission line inductor 313. Please refer to FIG. 3D, which illustrates a schematic diagram of an embodiment of a wideband impedance matching network of the present invention. The main structure of the embodiment of FIG. 3D is basically the same as the structure of the embodiment of FIG. 3C, except that the harmonic compensation matching network 30 further comprises a harmonic MN capacitor 314.

Please refer to FIG. 3E, which illustrates a schematic diagram of an embodiment of a wideband impedance matching network of the present invention. The main structure of the embodiment of FIG. 3E is basically the same as the structure of the embodiment of FIG. 3C, except that the fundamental MN first portion 10 comprises a first fundamental MN transmission line inductor 103. Please refer to FIG. 3F, which illustrates a schematic diagram of an embodiment of a wideband impedance matching network of the present invention. The main structure of the embodiment of FIG. 3F is basically the same as the structure of the embodiment of FIG. 3E, except that the fundamental MN first portion 10 further comprises a first fundamental MN capacitor 104.

Please refer to FIG. 3G, which illustrates a schematic diagram of an embodiment of a wideband impedance matching network of the present invention. The main structure of the embodiment of FIG. 3G is basically the same as the structure of the embodiment of FIG. 3E, except that the fundamental MN second portion 20 comprises a second fundamental MN transmission line inductor 203.

Please refer to FIG. 3H, which illustrates a schematic diagram of an embodiment of a wideband impedance matching network of the present invention. The main structure of the embodiment of FIG. 3H is basically the same as the structure of the embodiment of FIG. 3C, except that the fundamental MN second portion 20 comprises a second fundamental MN transmission line inductor 203.

Please refer to FIG. 31, which illustrates a schematic diagram of an embodiment of a wideband impedance matching network of the present invention. The main structure of the embodiment of FIG. 31 is basically the same as the structure of the embodiment of FIG. 3A, except that the fundamental MN first portion 10 comprises a first fundamental MN transmission line inductor 103. Please refer to FIG. 3J, which illustrates a schematic diagram of an embodiment of a wideband impedance matching network of the present invention. The main structure of the embodiment of FIG. 3J is basically the same as the structure of the embodiment of FIG. 3I, except that the fundamental MN first portion 10 further comprises a first fundamental MN capacitor 104.

Please refer to FIG. 3K, which illustrates a schematic diagram of an embodiment of a wideband impedance matching network of the present invention. The main structure of the embodiment of FIG. 3K is basically the same as the structure of the embodiment of FIG. 31, except that the fundamental MN second portion 20 comprises a second fundamental MN transmission line inductor 203.

Please refer to FIG. 3L, which illustrates a schematic diagram of an embodiment of a wideband impedance matching network of the present invention. The main structure of the embodiment of FIG. 3L is basically the same as the structure of the embodiment of FIG. 3A, except that the fundamental MN second portion 20 comprises a second fundamental MN transmission line inductor 203.

Please refer to FIG. 3M, which illustrates a schematic diagram of an embodiment of a wideband impedance matching network of the present invention. The main structure of the embodiment of FIG. 3M is basically the same as the structure of the embodiment of FIG. 3G, except that the harmonic compensation matching network 30 further comprises a harmonic MN capacitor 314 and the fundamental MN first portion 10 further comprises a first fundamental MN capacitor 104.

As disclosed in the above description and attached drawings, the present invention can provide a wideband impedance matching network. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A wideband impedance matching network comprising:
a fundamental output matching network, wherein said fundamental output matching network comprises:
a fundamental MN first portion formed on a semiconductor substrate, wherein said fundamental MN first portion has a first terminal and a second terminal; and
a fundamental MN second portion formed on said semiconductor substrate, wherein said fundamental MN second portion has a first terminal, wherein said second terminal of said fundamental MN first portion and said first terminal of said fundamental MN second portion are connected to an RF output terminal; and
a harmonic compensation matching network, wherein said harmonic compensation matching network comprises:
a harmonic MN portion formed on said semiconductor substrate, wherein said harmonic MN portion has a first terminal and a second terminal, wherein said first terminal of said fundamental MN first portion and said first terminal of said harmonic MN portion are connected to an RF input terminal; and
a harmonic MN backside via inductor formed on an outer surface of a harmonic MN backside via hole, wherein said harmonic MN backside via hole penetrating through said semiconductor substrate, wherein said harmonic MN backside via inductor has a first terminal and a second terminal, wherein said second terminal of said harmonic MN portion is connected to said first terminal of said harmonic MN backside via inductor, wherein said second terminal of said harmonic MN backside via inductor is grounded.

2. The wideband impedance matching network according to claim 1, wherein said harmonic MN portion comprises a harmonic MN transmission line inductor.

3. The wideband impedance matching network according to claim 2, wherein said harmonic MN portion further comprises a harmonic MN capacitor.

4. The wideband impedance matching network according to claim 2, wherein said fundamental MN first portion comprises a first fundamental MN transmission line inductor.

5. The wideband impedance matching network according to claim 4, wherein said fundamental MN first portion further comprises a first fundamental MN capacitor.

6. The wideband impedance matching network according to claim 4, wherein said fundamental MN second portion comprises a second fundamental MN transmission line inductor.

7. The wideband impedance matching network according to claim 6, wherein said harmonic MN portion further comprises a harmonic MN capacitor and said fundamental MN first portion further comprises a first fundamental MN capacitor.

8. The wideband impedance matching network according to claim 2, wherein said fundamental MN second portion comprises a second fundamental MN transmission line inductor.

9. The wideband impedance matching network according to claim 1, wherein said fundamental MN first portion comprises a first fundamental MN transmission line inductor.

10. The wideband impedance matching network according to claim 9, wherein said fundamental MN first portion further comprises a first fundamental MN capacitor.

11. The wideband impedance matching network according to claim 9, wherein said fundamental MN second portion comprises a second fundamental MN transmission line inductor.

12. The wideband impedance matching network according to claim 1, wherein said fundamental MN second portion comprises a second fundamental MN transmission line inductor.

13. The wideband impedance matching network according to claim 1, wherein said semiconductor substrate further comprises a fundamental MN backside via hole and said fundamental output matching network further comprises a fundamental MN backside via inductor, wherein said fundamental MN backside via inductor is formed on an outer surface of said fundamental MN backside via hole, wherein said fundamental MN backside via hole penetrates through said semiconductor substrate, wherein said fundamental MN backside via inductor has a first terminal and a second terminal, wherein said fundamental MN second portion has a second terminal, wherein said second terminal of said fundamental MN second portion is connected to said first terminal of said fundamental MN backside via inductor, wherein said second terminal of said fundamental MN backside via inductor is grounded.

14. The wideband impedance matching network according to claim 13, wherein said harmonic MN portion comprises a harmonic MN transmission line inductor.

15. The wideband impedance matching network according to claim 14, wherein said harmonic MN portion further comprises a harmonic MN capacitor.

16. The wideband impedance matching network according to claim 14, wherein said fundamental MN first portion comprises a first fundamental MN transmission line inductor.

17. The wideband impedance matching network according to claim 16, wherein said fundamental MN first portion further comprises a first fundamental MN capacitor.

18. The wideband impedance matching network according to claim 16, wherein said fundamental MN second portion comprises a second fundamental MN transmission line inductor.

19. The wideband impedance matching network according to claim 18, wherein said harmonic MN portion further comprises a harmonic MN capacitor and said fundamental MN first portion further comprises a first fundamental MN capacitor.

20. The wideband impedance matching network according to claim 14, wherein said fundamental MN second portion comprises a second fundamental MN transmission line inductor.

21. The wideband impedance matching network according to claim 13, wherein said fundamental MN first portion comprises a first fundamental MN transmission line inductor.

22. The wideband impedance matching network according to claim 21, wherein said fundamental MN first portion further comprises a first fundamental MN capacitor.

23. The wideband impedance matching network according to claim 21, wherein said fundamental MN second portion comprises a second fundamental MN transmission line inductor.

24. The wideband impedance matching network according to claim 13, wherein said fundamental MN second portion comprises a second fundamental MN transmission line inductor.

25. The wideband impedance matching network according to claim 1, wherein said semiconductor substrate is selected from the group consisting of: GaAs, InP, GaN, SiC, Si, sapphire, and SiGe.

26. A wideband impedance matching network comprising:
a harmonic compensation matching network formed on a semiconductor substrate, wherein said harmonic compensation matching network has a first terminal; and
a fundamental output matching network, wherein said fundamental output matching network comprises:
a fundamental MN first portion formed on said semiconductor substrate, wherein said fundamental MN first portion has a first terminal and a second terminal, wherein said first terminal of said fundamental MN first portion and said first terminal of said harmonic compensation matching network are connected to an RF input terminal;
a fundamental MN second portion formed on said semiconductor substrate, wherein said fundamental MN second portion has a first terminal and a second terminal, wherein said second terminal of said fundamental MN first portion and said first terminal of said fundamental MN second portion are connected to an RF output terminal; and
a fundamental MN backside via inductor formed on an outer surface of a fundamental MN backside via hole, wherein said fundamental MN backside via hole penetrating through said semiconductor substrate, wherein said fundamental MN backside via inductor has a first terminal and a second terminal, wherein said second terminal of said fundamental MN second portion is connected to said first terminal of said fundamental MN backside via inductor, wherein said second terminal of said fundamental MN backside via inductor is grounded.

27. The wideband impedance matching network according to claim 26, wherein said harmonic compensation matching network comprises a harmonic MN transmission line inductor.

28. The wideband impedance matching network according to claim 27, wherein said harmonic compensation matching network further comprises a harmonic MN capacitor.

29. The wideband impedance matching network according to claim 27, wherein said fundamental MN first portion comprises a first fundamental MN transmission line inductor.

30. The wideband impedance matching network according to claim 29, wherein said fundamental MN first portion further comprises a first fundamental MN capacitor.

31. The wideband impedance matching network according to claim 29, wherein said fundamental MN second portion comprises a second fundamental MN transmission line inductor.

32. The wideband impedance matching network according to claim 31, wherein said harmonic compensation matching network further comprises a harmonic MN capacitor and said fundamental MN first portion further comprises a first fundamental MN capacitor.

33. The wideband impedance matching network according to claim 27, wherein said fundamental MN second portion comprises a second fundamental MN transmission line inductor.

34. The wideband impedance matching network according to claim 26, wherein said fundamental MN first portion comprises a first fundamental MN transmission line inductor.

35. The wideband impedance matching network according to claim 34, wherein said fundamental MN first portion further comprises a first fundamental MN capacitor.

36. The wideband impedance matching network according to claim 34, wherein said fundamental MN second portion comprises a second fundamental MN transmission line inductor.

37. The wideband impedance matching network according to claim 26, wherein said fundamental MN second portion comprises a second fundamental MN transmission line inductor.

38. The wideband impedance matching network according to claim 26, wherein said semiconductor substrate is selected from the group consisting of: GaAs, InP, GaN, SiC, Si, sapphire, and SiGe.
